(19) United States
(12) Patent Application Publication
(10) Pub. No.: US 2017/0298500 A1
(43) Pub. Date: Oct. 19, 2017

(54) TARGET SPUTTERING DEVICE AND METHOD FOR SPUTTERING TARGET

(71) Applicant: BOE TECHNOLOGY GROUP CO., LTD., Beijing (CN)

(72) Inventor: Yu Wei, Beijing (CN)

(21) Appl. No.: 15/324,260

(22) PCT Filed: Jan. 29, 2016
(86) PCT No.: PCT/CN2016/072745

§ 371 Date: Jan. 5, 2017

(30) Foreign Application Priority Data
Sep. 17, 2015 (CN) 201510594168.4

(51) Int. Cl. C23C 14/35; H01J 37/34; H01F 7/20; C23C 14/34

(52) U.S. Cl. CPC C23C 14/35; H01J 37/3435; C23C 14/3407; H01F 7/20; H01J 37/3408

(57) ABSTRACT

A target sputtering device includes: a back plate; and a plurality of electromagnetic coil units uniformly distributed underneath the back plate and insulated with each other, wherein the plurality of electromagnetic coil units are configured to generate a magnetic field, which is movable relative to the back plate and orthogonal to the back plate, in a preset period. There is further disclosed a method for sputtering a target using the above-described target sputtering device.

### CROSS-REFERENCE TO RELATED APPLICATION

This application is a Section 371 National Stage Application of International Application No. PCT/CN2016/072745, filed on Jan. 29, 2016, entitled “TARGET SPUTTERING DEVICE AND METHOD FOR SPUTTERING TARGET”, which claims priority to Chinese Application No. 201510594168.4, filed on Sep. 17, 2015, incorporated herein by reference in their entirety.

### BACKGROUND OF THE INVENTION

### Field of the Invention

Embodiments of the present disclosure relate to a field of sputtering technology, and more particularly, to a target sputtering device and a method for sputtering a target.

### Description of the Related Art

Magnetron sputtering technology has been widely used in a semiconductor industry, a flat panel display industry, etc. The magnetic field of a conventional magnetron sputtering source is generally formed such that the magnetic field is relatively fixed with respect to a target substrate.

### SUMMARY OF THE INVENTION

The embodiments of the present disclosure provide a target sputtering device and a method for sputtering a target, so as to improve the uniformity of the magnetic field distribution of the target sputtering device, and further improve the use efficiency of the target.

The embodiments of the present disclosure provide a target sputtering device, comprising:

a back plate; and

a plurality of electromagnetic coil units uniformly distributed underneath the back plate and insulated with each other,

wherein the plurality of electromagnetic coil units are configured to generate a magnetic field, which is movable relative to the back plate and orthogonal to the back plate, in a preset period.

According to the embodiments of the present disclosure, the target sputtering device comprises a back plate and a plurality of electromagnetic coil units uniformly distributed underneath the back plate and insulated with each other. When alternating currents are loaded to the plurality of electromagnetic coil units, the plurality of electromagnetic coil units generate a magnetic field. Furthermore, the plurality of electromagnetic coil units are configured to generate a magnetic field, which is movable relative to the back plate and orthogonal to the back plate, in a preset period. Thus, the magnetic field orthogonal to the back plate is generated at each time in the preset period, and in the preset period, each of the electromagnetic coil units generates different magnetic fields at different times so that the magnetic field moves relative to the back plate. Since a time average value of magnetic induction intensity in the preset period at one position within an effective area of the surface of the back plate is identical to that at the other positions within an effective area of the surface of the back plate, and the electromagnetic coil units are uniformly distributed, the magnetic field is uniformly distributed around the back plate so that the distribution uniformity of the magnetic field generated by the target sputtering device is improved, thereby improving the use efficiency of the target.

Optionally, the magnetic field generated by the plurality of electromagnetic coil units reciprocates relative to the back plate in the preset period.

By means of allowing the magnetic field generated by the plurality of electromagnetic coil units to reciprocate relative to the back plate, the magnetic field may cover the whole back plate, and the magnetic field is uniformly distributed, thereby improving the use efficiency of the target.

Optionally, at a time in the preset period, preset alternating currents are only loaded to spaced-apart electromagnetic coil units, each two adjacent ones of which are spaced apart from each other with a predetermined number of electromagnetic coil units located therein, and the electromagnetic coil units loaded with the preset alternating currents at said time are different from the electromagnetic coil units loaded with the preset alternating currents at a next time.

Optionally, directions of the preset alternating currents loaded to two adjacent ones of said spaced-apart electromagnetic coil units at a same time are identical or opposite to each other, and the preset alternating currents have a same effective value.

Optionally, the electromagnetic coil units comprise an iron core and coils wound around the iron core, and the number of the coils in one electromagnetic coil unit is equal to the number of the coils in any other electromagnetic coil units.

By means of allowing the electromagnetic coil units to be identical to each other, the magnetic induction intensities from the electromagnetic coil units are the same.

Optionally, the coils in the electromagnetic coil units have a rectangular shape, and a long side of the rectangle is parallel to the back plate and perpendicular to a long side of the back plate.

By means of allowing the long side of the rectangular coil to be perpendicular to the long side of the back plate, the magnetic field generated by the electromagnetic coil unit may be substantially distributed around the back plate, thereby increasing the magnetic field intensity.

Optionally, a short side of the rectangle is in a range of 50-500 mm.

Optionally, two adjacent ones of the electromagnetic coil units are spaced apart from each other by a gap of 5-50 mm.

By means of providing the gap between two adjacent electromagnetic coil units, it is possible to prevent interference between the adjacent electromagnetic coil units.

The embodiments of the present disclosure further provide a method for sputtering a target using the target sputtering device according to the embodiments of the present disclosure, the method comprises a step of:

at a time in the preset period, loading preset alternating currents to only spaced-apart electromagnetic coil units, each two adjacent ones of which are spaced apart from each other with a predetermined number of electromagnetic coil units located therein,

wherein the electromagnetic coil units loaded with the preset alternating currents at said time are different from the electromagnetic coil units loaded with the preset alternating currents at a next time.

In the method for sputtering the target according to the embodiments of the present disclosure, at a time in the preset period, the preset alternating currents are only loaded to the spaced-apart electromagnetic coil units, each two adjacent ones of which are spaced apart from each other with a predetermined number of electromagnetic coil units located therein, so that there is a magnetic field generated by the electromagnetic coil units at each time. Furthermore, the electromagnetic coil units loaded with the preset alternating currents at said time are different from the electromagnetic coil units loaded with the preset alternating currents at a next time, so that the magnetic field is generated by the electromagnetic coil units, which are different from the electromagnetic coil units operated at any other times in the preset period. In such a way, the magnetic field moves relative to the back plate, thus the uniformity of the magnetic field is improved, the uniformity of the sputtering operation is improved, and the use efficiency of the target is improved.

Optionally, the method further comprises a step of: sequentially loading the preset alternating currents to the electromagnetic coil units along the back plate in a reciprocation manner, during the preset period.

By means of sequentially loading the preset alternating currents to the electromagnetic coil units along the back plate in a reciprocation manner, the uniformity of the magnetic field may be improved, and the coverage area of the magnetic field may be increased, thereby improving the use efficiency of the target.

Optionally, directions of the preset alternating currents loaded to two adjacent ones of said spaced-apart electromagnetic coil units at a same time are identical or opposite to each other, and the preset alternating currents have a same effective value.

### BRIEF DESCRIPTION OF THE DRAWINGS

FIG. 1 is a schematic structural view of a target sputtering device;

FIG. 2a is a cross-sectional schematic view of a target sputtering device according to an embodiment of the present disclosure;

FIG. 2b is a left side view of the target sputtering device according to the embodiment of the present disclosure;

FIG. 2c is a bottom view of the target sputtering device according to the embodiment of the present disclosure;

FIG. 3a is a first schematic view of a magnetic field distribution in a target sputtering device according to an embodiment of the present disclosure;

FIG. 3b is a second schematic view of a magnetic field distribution in a target sputtering device according to an embodiment of the present disclosure;

FIG. 3c is a third schematic view of a magnetic field distribution in a target sputtering device according to an embodiment of the present disclosure;

FIG. 4 is a fourth schematic view of a magnetic field distribution in a target sputtering device according to an embodiment of the present disclosure;

FIG. 5 is a fifth schematic view of a magnetic field distribution in a target sputtering device according to an embodiment of the present disclosure;

FIG. 6 is a sixth schematic view of a magnetic field distribution in a target sputtering device according to an embodiment of the present disclosure;

FIG. 7 is a seventh schematic view of a magnetic field distribution in a target sputtering device according to an embodiment of the present disclosure;

FIG. 8 is an eighth schematic view of a magnetic field distribution in a target sputtering device according to an embodiment of the present disclosure;

FIG. 9 is a schematic view of a gap between the electromagnetic coil units in a target sputtering device according to an embodiment of the present disclosure;

FIG. 10 is a first schematic view of a method for sputtering a target according to an embodiment of the present disclosure;

FIG. 11 is a second schematic view of a method for sputtering a target according to an embodiment of the present disclosure;

FIG. 12 is a third schematic view of a method for sputtering a target according to an embodiment of the present disclosure;

FIG. 13 is a fourth schematic view of a method for sputtering a target according to an embodiment of the present disclosure;

FIG. 14 is a fifth schematic view of a method for sputtering a target according to an embodiment of the present disclosure.

### DETAILED DESCRIPTION OF PREFERRED EMBODIMENTS OF THE INVENTION

In order to clearly understand the objectives, technical solutions and advantages of the present disclosure, the present disclosure will be described in detail below with reference to the accompanying drawings. Obviously, the described embodiments are merely a part of the present disclosure, rather than all of the present disclosure. Any other embodiments obtained by those skilled in the art based on the embodiments of the present disclosure without creative effort may fall into the scope of the present disclosure.

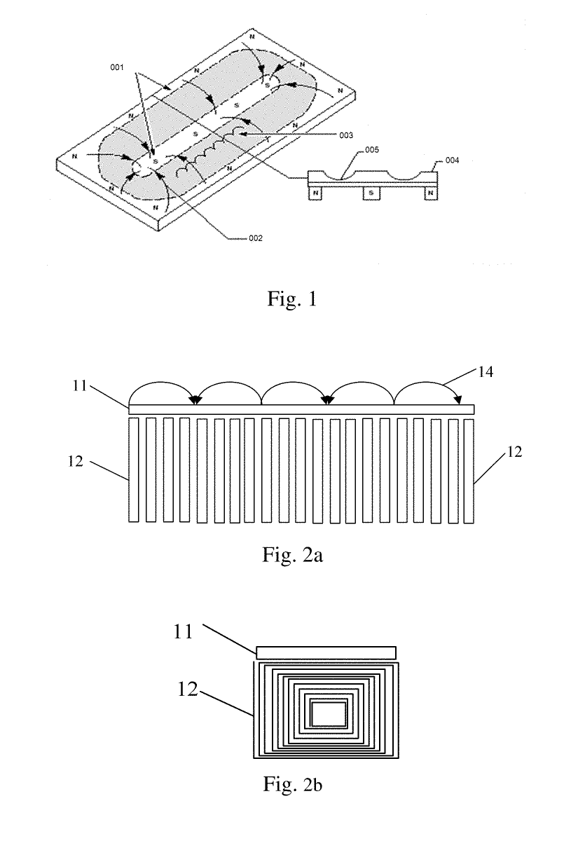

As shown in FIG. 1, a cylindrical magnet portion located centrally and a ring-shaped magnet portion located around the cylindrical magnet portion and having an opposite magnetic pole to the magnetic pole of the cylindrical magnet portion are arranged to generate a closed magnetic circuit, and the closed magnetic circuit and an electric field on a substrate surface forms an orthogonal field such that electrons perform larmor gyration around the magnetic field. The existence of the larmor gyration extends motion path of the electrons between the two poles, and increases collision probability of the electrons, thus build-up of luminance under low voltage becomes possible. Furthermore, the increase of the collision probability allows ionization degree of gas molecules in a plasma to be increased, thereby improving use efficiency of the target. As shown in FIG. 1, reference numeral 001 refers to poles formed by a ring-shaped magnet, reference numeral 002 refers to magnetic field lines of the ring-shaped magnet, reference numeral 003 refers to electrons which are driven to perform larmor gyration under the action of a magnetic field, reference numeral 004 refers to a target located above the ring-shaped magnet, and reference numeral 005 refers to an etched region which is etched under the action of the magnetic field.

However, the magnetic field having the above-described magnetic field distribution structure has a relatively small uniformity area, as a result, the etched region of the target is relatively concentrated. As shown in FIG. 1, the target surface is formed with runway-shaped grooves, resulting in a low use efficiency of the target. Generally, the use efficiency of the target for a flat target magnetron sputtering device used in a production line of Large Generation Panel is less than 40%, resulting in target waste. Furthermore, the target needs to be frequently replaced, resulting in a decreased operation ratio of equipment. Typically, such drawbacks may be improved by changing the magnetic field distribution structure, or moving the magnet relative to the target, however, most of these means have complex structures, with a decreased reliability of equipment, and it is more difficult for them to be applied to the production line of Large Generation Panel.

As described above, the non-uniform magnetic field distribution of the target sputtering device results in a relatively low use efficiency for target.

The embodiments of the present disclosure provide a target sputtering device and a method for sputtering a target, so as to improve the distribution uniformity of the magnetic field generated by the target sputtering device, and further improve the use efficiency of the target.

### First Embodiment

As shown in FIG. 2a, the target sputtering device according to the embodiment of the present disclosure comprises: a back plate 11; and a plurality of electromagnetic coil units 12 uniformly distributed underneath the back plate 11 and insulated with each other.

The plurality of electromagnetic coil units 12 are configured to generate a magnetic field 14, which is movable relative to the back plate 11 and orthogonal to the back plate 11, in a preset period. Also, a time average value of magnetic induction intensity in the preset period at one position within an effective area of the surface of the back plate is identical to that at the other positions within the effective area of the surface of the back plate (FIG. 2a is a cross-sectional schematic view of a target sputtering device according to an embodiment of the present disclosure, the schematic view only shows a magnetic field distribution at one time, and the direction of the magnetic field is only an example, and it is not intended to be limited to the direction as shown).

It should be noted that, in the preset period, the generated magnetic field may move relative to the back plate from left to right, or the generated magnetic field may move relative to the back plate from right to left, or the generated magnetic field may move relative to the back plate firstly from left to right and then from right to left, or the generated magnetic field may move relative to the back plate firstly from right to left and then from left to right, in order to realize the relative movement of the magnetic field relative to the back plate. Furthermore, the generation of the magnetic field by the plurality of electromagnetic coil units may refer to that each of the plurality of electromagnetic coil units sequentially generates a magnetic field in such a way that the magnetic field generated by the plurality of electromagnetic coil units moves relative to the back plate, or that two electromagnetic coil units are loaded with different alternating currents to generate a magnetic field of a fixed direction in such a way that the magnetic field generated by each two electromagnetic coil units moves relative to the back plate. In addition, the relative movement of the magnetic field may include that the magnetic field distributed around the whole back plate moves in a predetermined direction all the time and moves from the left side to the right side of the back plate, or may include dividing the continuously arranged electromagnetic coil units into a plurality of groups such that the magnetic field generated by each group or two adjacent groups moves relative to the back plate in the preset period.

The preset period may be determined according to the size of the target, etc., in a practical application of the target sputtering device, in order to facilitate uniform distribution of the magnetic field around the back plate.

In order to more clearly describe the target sputtering device according to the embodiment of the present disclosure, FIG. 2a and FIG. 2b are provided. FIG. 2a is a cross-sectional schematic view of a target sputtering device according to an embodiment of the present disclosure. FIG. 2b is a left side view of the target sputtering device according to the embodiment of the present disclosure, in which the electromagnetic coil units have an iron core.

According to the embodiment of the present disclosure, the target sputtering device comprises a back plate and a plurality of electromagnetic coil units uniformly distributed underneath the back plate and insulated with each other. When alternating currents are loaded to the plurality of electromagnetic coil units, the plurality of electromagnetic coil units generate a magnetic field. Furthermore, the plurality of electromagnetic coil units are configured to generate a magnetic field, which is movable relative to the back plate and orthogonal to the back plate, in a preset period. Thus, the magnetic field orthogonal to the back plate is generated at each time in the preset period, and in the preset period, each of the electromagnetic coil units generates different magnetic fields at different times so that the magnetic field moves relative to the back plate. Since a time average value of magnetic induction intensity in the preset period at one position within an effective area of the surface of the back plate is identical to that at the other positions within the effective area of the surface of the back plate, and the electromagnetic coil units are uniformly distributed, the magnetic field is uniformly distributed around the back plate so that the distribution uniformity of the magnetic field generated by the target sputtering device is improved, thereby improving the use efficiency of the target.

Optionally, the magnetic field generated by the plurality of electromagnetic coil units reciprocates relative to the back plate in the preset period.

It should be noted that the plurality of electromagnetic coil units generate a magnetic field orthogonal to the back plate in the preset period in such a way that the magnetic field reciprocates relative to the back plate. The reciprocation may be a movement firstly from left to right and then from right to left, or a movement firstly from right to left and then from left to right, and they are not particularly limited in the embodiments of the present disclosure. Furthermore, the generation of the magnetic field by the plurality of electromagnetic coil units may refer to that each of the plurality of electromagnetic coil units sequentially generates a magnetic field in such a way that the magnetic field generated by the plurality of electromagnetic coil units moves relative to the back plate, or that two electromagnetic coil units are loaded with different alternating currents to generate a magnetic field of a fixed direction in such a way that the magnetic field generated by each two electromagnetic coil units moves relative to the back plate.

Next, the embodiments of the present disclosure will be described with reference to schematic views, so as to more clearly understand the reciprocation of the magnetic field relative to the back plate. It should be noted that, in order to embody that each electromagnetic coil unit comprises a plurality of rectangular coils, the electromagnetic coil units are represented by curved lines to describe the magnetic field distribution, however, they are rectangle as shown in FIGS. 1, 2a, 2b and 2c.

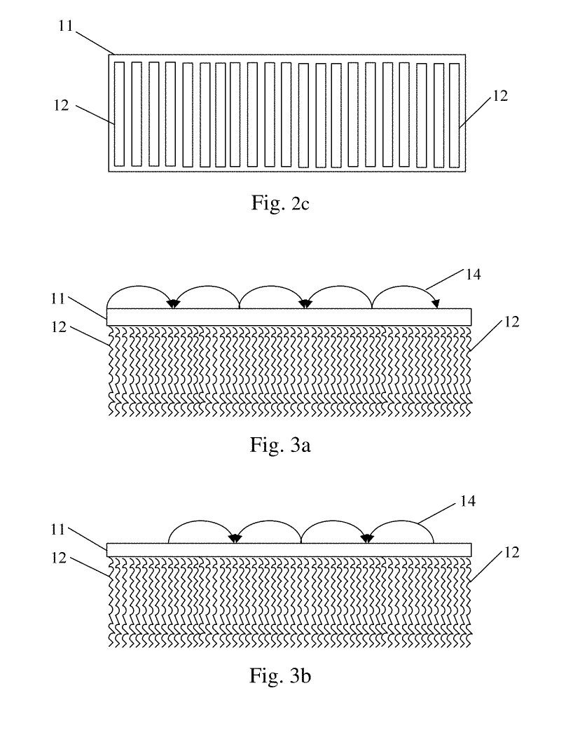

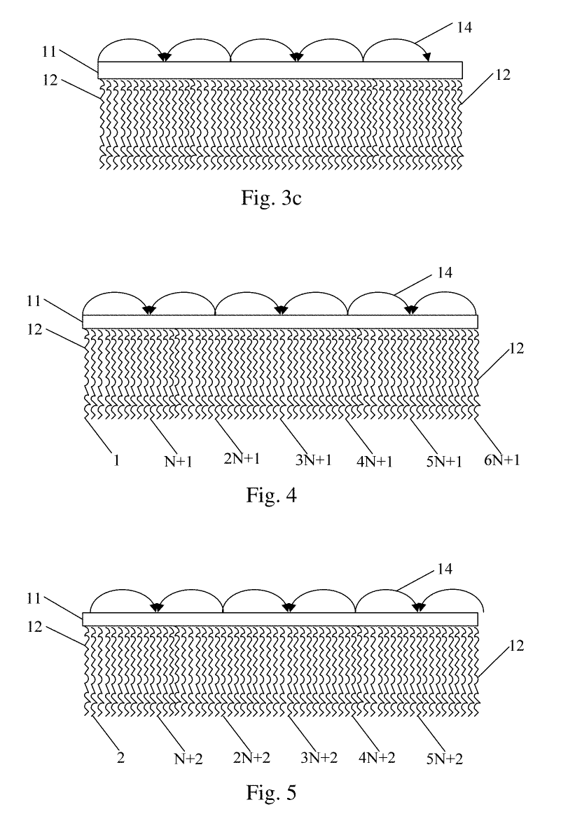

Referring to FIGS. 3a, 3b and 3c, the magnetic field 14 is alternately distributed around the back plate as shown in FIG. 3a, the distribution of the magnetic field 14 in FIG. 3b is moved towards the right side with respect to that in FIG. 3a, and the distribution of the magnetic field 14 in FIG. 3c is moved towards the left side with respect to that in FIG. 3b, thereby achieving the reciprocation of the magnetic field relative to the back plate. The magnetic field distribution is not limited to that shown in FIGS. 3a, 3b and 3c, they all fall into the scope of the present disclosure as long as the reciprocation or relative movement of the magnetic field relative to the back plate may be achieved.

By means of allowing the magnetic field generated by the plurality of electromagnetic coil units to reciprocate relative to the back plate in the preset period, the magnetic field may cover the whole back plate, and the magnetic field is uniformly distributed, thereby improving the use efficiency of the target.

Optionally, at a time in the preset period, preset alternating currents are only loaded to spaced-apart electromagnetic coil units, each two adjacent ones of which are spaced apart from each other with a predetermined number of electromagnetic coil units located therein, and the electromagnetic coil units loaded with the preset alternating currents at said time are different from the electromagnetic coil units loaded with the preset alternating currents at a next time.

It should be noted that, it is not intended to limit the concrete value of the predetermined number of electromagnetic coil units located between the two adjacent ones of the spaced-apart electromagnetic coil units in the embodiments of the present disclosure. For example, it may be set to 5, 10, and so on. The preset alternating currents may be sinusoidal alternating currents or any other alternating currents. It should be noted that, if the two adjacent ones of the spaced-apart electromagnetic coil units are loaded with the same preset alternating currents, then the electromagnetic coil units will generate magnetic fields having the same direction; if the two adjacent ones of the spaced-apart electromagnetic coil units are respectively loaded with preset alternating currents of opposite directions, then one of said two adjacent spaced-apart electromagnetic coil units functions as a N pole, and the other functions as a S pole, thereby generating a magnetic field of fixed direction.

Optionally, the directions of the preset alternating currents loaded to two adjacent ones of said spaced-apart electromagnetic coil units at the same time are the same or opposite to each other, and the preset alternating currents have the same effective value.

In order to allow the magnetic fields generated by the electromagnetic coil units to have the same magnetic field intensity, the loaded preset alternating currents are configured to have the same effective value. If the loaded preset alternating currents have the same direction, then the electromagnetic coil units generate magnetic fields having the same magnetic field direction in accordance with physical characteristic of electromagnetism. In order to increase the magnetic field intensity orthogonal to the back plate, optionally, the directions of the preset alternating currents loaded to two adjacent ones of said spaced-apart electromagnetic coil units are opposite to each other. For example, the preset alternating current loaded to the first electromagnetic coil unit is a sinusoidal alternating current, and the preset alternating current loaded to the second electromagnetic coil unit, which is spaced apart from the first electromagnetic coil unit with the predetermined number of electromagnetic coil units located therein, is an alternating current which has a 180° phase difference from the sinusoidal alternating current, so that the direction of the magnetic field generated by the first electromagnetic coil unit is opposite to the direction of the magnetic field generated by the second electromagnetic coil unit. In this way, one of the electromagnetic coil units may be considered as an N pole, and the other one of the electromagnetic coil units may be considered an S pole, and the magnetic field intensity generated by such two electromagnetic coil units is significantly larger than the magnetic field intensity generated by only one electromagnetic coil unit.

In order to explain in more detail that the preset alternating currents are only loaded to the spaced-apart electromagnetic coil units, each two adjacent ones of which are spaced apart from each other with the predetermined number of electromagnetic coil units located therein, at a time, the following description will be made by way of example.

For example, the predetermined number is set to be N, and the number of the electromagnetic coil units located underneath the back plate is (M+1)*N, where M and N are both positive integers and N is much less than M. Furthermore, the loaded preset alternating currents are the alternating currents having opposite directions, that is, a first alternating current and a second alternating current.

At a first time in the preset period, as shown in FIG. 4, the first alternating current is loaded to the first electromagnetic coil unit 12, and the second alternating current is loaded to the (N+1)th electromagnetic coil unit 12; at the same time, the first alternating current is loaded to the (2N+1)th electromagnetic coil unit 12, and the second alternating current is loaded to the (3N+1)th electromagnetic coil unit 12, and so on; finally, the alternating current is loaded to the (M*N+1)th electromagnetic coil unit 12. Thus, it generates a magnetic field 14 shown in FIG. 4.

At a second time in the preset period, as shown in FIG. 5, the loading of the alternating currents to the first, (N+1)th, (2N+1)th, (3N+1)th, . . . , (M*N+1)th electromagnetic coil units is stopped; at the same time, the first alternating current is loaded to the second electromagnetic coil unit 12, and the second alternating current is loaded to the (N+2)th electromagnetic coil unit 12; at the same time, the first alternating current is loaded to the (2N+2)th electromagnetic coil unit 12, and the second alternating current is loaded to the (3N+2)th electromagnetic coil unit 12, and so on; finally, the alternating current is loaded to the (M*N+2)th electromagnetic coil unit 12. Thus, it generates a magnetic field 14 shown in FIG. 5.

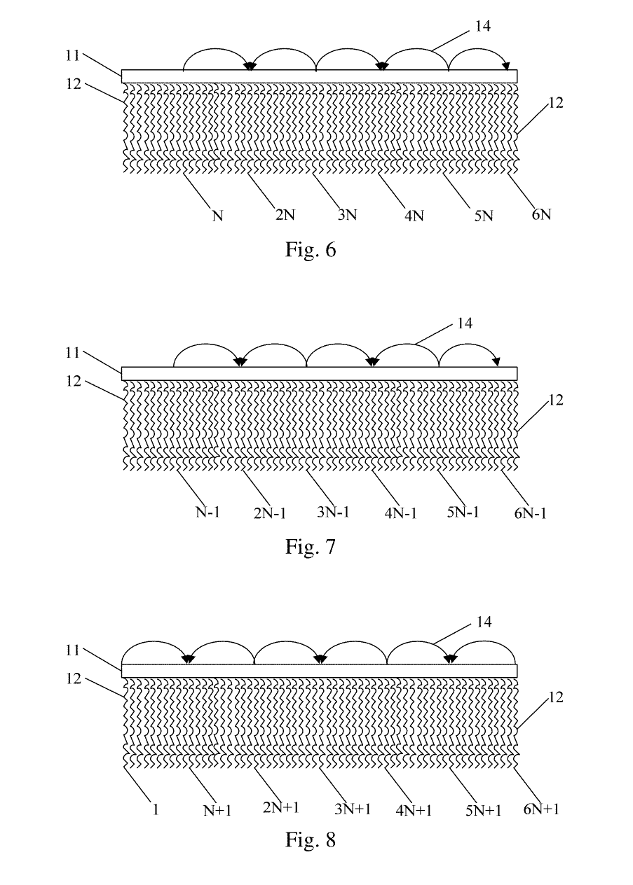

Similarly, as shown in FIG. 6, the loading of the alternating currents to the (N−1)th, (2N−1)th, (3N−1)th, (4N−1)th, . . . , ((M+1)*N−1)th electromagnetic coil units is stopped; at the same time, the first alternating current is loaded to the Nth electromagnetic coil unit 12, and the second alternating current is loaded to the (2N)th electromagnetic coil unit 12; at the same time, the first alternating current is loaded to the (3N)th electromagnetic coil unit 12, and the second alternating current is loaded to the (4N)th electromagnetic coil unit 12, and so on; finally, the alternating current is loaded to the ((M+1)*N)th electromagnetic coil unit 12. Thus, it generates a magnetic field 14 shown in FIG. 6.

At the next time, as shown in FIG. 7, the loading of the alternating currents to the Nth, (2N)th, (3N)th, . . . , ((M+1)*N)th electromagnetic coil units is stopped; at the same time, the first alternating current is loaded to the (N−1)th electromagnetic coil unit 12, and the second alternating current is loaded to the (2N−1)th electromagnetic coil unit 12; at the same time, the first alternating current is loaded to the (3N−1)th electromagnetic coil unit 12, and the second alternating current is loaded to the (4N−1)th electromagnetic coil unit 12, and so on; finally, the alternating current is loaded to the ((M+1)*N−1)th electromagnetic coil unit 12. Thus, it generates a magnetic field 14 shown in FIG. 7.

Similarly, at the last time in the preset period, as shown in FIG. 8, the loading of the alternating currents to the second, (N+2)th, (2N+2)th, . . . , (M*N+2)th electromagnetic coil units is stopped; at the same time, the first alternating current is loaded to the first electromagnetic coil unit 12, and the second alternating current is loaded to the (N+1)th electromagnetic coil unit 12; at the same time, the first alternating current is loaded to the (2N+1)th electromagnetic coil unit 12, and the second alternating current is loaded to the (3N+1)th electromagnetic coil unit 12, and so on; finally, the alternating current is loaded to the (M*N+1)th electromagnetic coil unit 12. Thus, it generates a magnetic field 14 shown in FIG. 8.

By means of the above-described steps of loading the alternating currents, it achieves the reciprocation of the magnetic field generated by the electromagnetic coil units relative to the back plate.

It should be noted that the magnetic fields shown in FIGS. 4 to 8 are only an optional embodiment of the present disclosure, and the reciprocation of the magnetic field can also be achieved by other means.

Optionally, the electromagnetic coil units 12 comprise an iron core and coils wound around the iron core, and the number of the coils in one electromagnetic coil unit is equal to the number of the coils in any other electromagnetic coil units.

In the embodiment of the present disclosure, the electromagnetic coil unit consists of an iron core and multiple rounds of coils wound around the iron core. As for the number of the rounds of the coils, it is not limited in the embodiment of the present disclosure. If variable currents are supplied to multiple rounds of coils, the enclosed coils will generate a magnetic field. Therefore, the electromagnetic coil units according to the embodiment of the present disclosure are intended to generate a magnetic field, such that ions collide with each other under the action of the magnetic field, thereby facilitating the etching of the target.

It should be noted that, if the iron core is a rectangular parallelepiped or a cube, then the coil is a rectangular coil; if the iron core is a spheroid, then the coil is circular. Therefore, the coil according to the embodiment of the present disclosure may be a rectangular coil or a circular coil.

By means of allowing the electromagnetic coil units to be identical to each other, the magnetic induction intensities or densities from the electromagnetic coil units are the same when the same or opposite alternating currents are supplied.

Optionally, the coils in the electromagnetic coil units have a rectangular shape, and a long side of the rectangle is parallel to the back plate and perpendicular to a long side of the back plate.

In particular, if the coils in the electromagnetic coil units have a rectangular shape, then the long side of the rectangular coil is arranged to be parallel to the back plate and perpendicular to the long side of the back plate. In this way, the magnetic field generated by the electromagnetic coil unit may be substantially distributed around the back plate, thereby increasing the magnetic field intensity around the back plate. Alternatively, it is possible to arrange the short side of the rectangular coil in the electromagnetic coil unit to be parallel to the back plate and perpendicular to the long side of the back plate. In the embodiment of the present disclosure, the arrangement that the long side of the rectangular coil is parallel to the back plate and perpendicular to the long side of the back plate is provided as an optional example.

By means of allowing the long side of the rectangular coil to be perpendicular to the long side of the back plate, the magnetic field generated by the electromagnetic coil unit may be substantially distributed around the back plate. If the variable current is supplied to the rectangular coil, the rectangular coil will generate a magnetic field and the magnetic field in a space where the long side of the coil is located is more intense than the magnetic field in a space where the short side of the coil is located, thus, the magnetic lines of the magnetic field in the space where the long side of the coil is located are allowed to pass through the back plate more effectively.

Optionally, a short side of the rectangle is in a range of 50-500 mm.

According to a practical application of the target sputtering device, the short side of the rectangular coil is generally in a range of 50-500 mm. That is to say, the height of the electromagnetic coil unit located underneath the back plate is in a range of 50-500 mm. However, the short side of the rectangle is not limited to 50-500 mm, it may be designed to be greater than 500 mm or less than 50 mm if required.

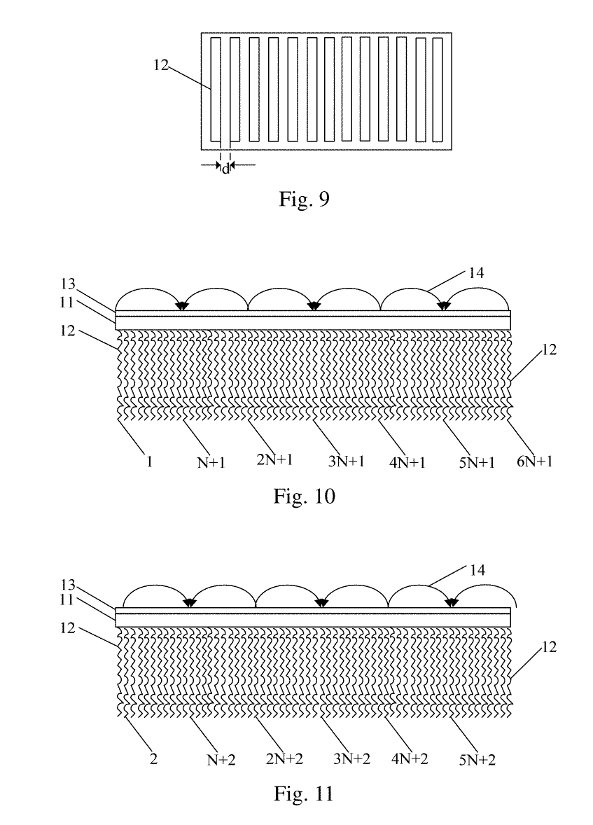

Optionally, as shown in FIG. 9, two adjacent ones of the electromagnetic coil units 12 are spaced apart from each other by a gap d of 5-50 mm.

By means of providing the gap between two adjacent electromagnetic coil units, it is possible to prevent interference between the adjacent electromagnetic coil units.

If the adjacent electromagnetic coil units generate magnetic fields at the same time, they will interfere with each other. In order to insulate the adjacent electromagnetic coil units from each other, a fixed gap may be provided. Therefore, a gap is provided between each two adjacent electromagnetic coil units. The gap may be in a range of 5-50 mm, as an optional range, which can ensure that the magnetic fields generated by the adjacent electromagnetic coil units do not produce mutual inductance and any other interference. However, the value of the gap is not limited thereto in the embodiments of the present disclosure.

It should be emphasized that, in order to make the entire surface of the back plate be in the magnetic field, a plurality of electromagnetic coil units are evenly distributed underneath the back plate, so that the magnetic field generated by the electromagnetic coil units uniformly covers the whole back plate, thereby increasing the magnetic field distribution range of the target sputtering device.

In summary, in the target sputtering device according to the embodiment of the present disclosure, in replacement of a permanent magnet in the prior art, a plurality of electromagnetic coil units having the same structure and insulated with each other are uniformly distributed underneath the whole back plate, so that the magnetic field generated by supplying the preset alternating currents to the electromagnetic coil units may uniformly cover the whole back plate. By means of allowing the magnetic field generated by the plurality of electromagnetic coil units to reciprocate relative to the back plate, the magnetic field from the target sputtering device may be relatively uniformly distributed. Furthermore, due to the same preset alternating currents and the same structures of the electromagnetic coil units, the magnetic densities or magnetic induction intensities from the electromagnetic coil units are the same. Moreover, in the embodiment of the present disclosure, the long side of the rectangular coil of the electromagnetic coil unit is perpendicular to the long side of the back plate, so that a great portion of the magnetic field generated by each of the electromagnetic coil units may pass through the back plate. In addition, a gap is provided between two adjacent electromagnetic coil units, so that the magnetic field generated by the electromagnetic coil units may be uniformly distributed around the back plate. In a word, the target sputtering device according to the embodiment of the present disclosure increases the distribution uniformity of the magnetic field and the distribution range of the magnetic field, thereby improving the use efficiency of the target.

Next, a method for sputtering a target using the target sputtering device will be described.

The embodiment of the present disclosure provides a method for sputtering a target using the target sputtering device according to the embodiments of the present disclosure, the method comprises: at a time in the preset period, loading preset alternating currents to only spaced-apart electromagnetic coil units, each two adjacent ones of which are spaced apart from each other with a predetermined number of electromagnetic coil units located therein, and wherein the electromagnetic coil units loaded with the preset alternating currents at said time are different from the electromagnetic coil units loaded with the preset alternating currents at a next time.

The preset period may be determined according to the size of the target, etc., in a practical application of the target sputtering device, in order to facilitate uniform distribution of the magnetic field around the back plate.

It is not intended to limit the concrete value of the predetermined number of electromagnetic coil units located between the two adjacent ones of the spaced-apart electromagnetic coil units in the embodiments of the present disclosure. For example, it may be set to 5, 10, and so on. The preset alternating currents may be sinusoidal alternating currents or any other alternating currents. It should be noted that, if the two adjacent ones of the spaced-apart electromagnetic coil units are loaded with the same preset alternating currents, then the electromagnetic coil units will generate magnetic fields having the same direction; if the two adjacent ones of the spaced-apart electromagnetic coil units are respectively loaded with preset alternating currents of opposite directions, then one of said two adjacent spaced-apart electromagnetic coil units functions as a N pole, and the other functions as a S pole, thereby generating a magnetic field of fixed direction.

It should be noted that, by means of loading the preset alternating currents, the plurality of electromagnetic coil units may generate a magnetic field orthogonal to the back plate, and the electromagnetic coil units loaded with the preset alternating currents at different times are different, such that the magnetic field reciprocates relative to the back plate in the preset period. The reciprocation may be a movement firstly from left to right and then from right to left, or a movement firstly from right to left and then from left to right, and they are not particularly limited in the embodiments of the present disclosure.

In the method for sputtering the target according to the embodiment of the present disclosure, at a time in the preset period, the preset alternating currents are only loaded to the spaced-apart electromagnetic coil units, each two adjacent ones of which are spaced apart from each other with a predetermined number of electromagnetic coil units located therein, so that there is a magnetic field generated by the electromagnetic coil units at each time. Furthermore, the electromagnetic coil units loaded with the preset alternating currents at said time are different from the electromagnetic coil units loaded with the preset alternating currents at a next time, so that the magnetic field is generated by the electromagnetic coil units, which are different from the electromagnetic coil units operated at any other times in the preset period. In such a way, the magnetic field moves relative to the back plate, thus the uniformity of the magnetic field is improved, the uniformity of the sputtering operation is improved, and the use efficiency of the target is improved.

Optionally, the method further comprises a step of: sequentially loading the preset alternating currents to the electromagnetic coil units along the back plate in a reciprocation manner, during the preset period.

In particular, the loading of the preset alternating currents may be sequentially performed from left to right, or from right to left, or firstly from left to right and then from right to left, or firstly from right to left and then from left to right. In order to increase the uniformity and the coverage area of the magnetic field, the preset alternating currents are sequentially loaded firstly from left to right and then from right to left, or firstly from right to left and then from left to right. Thus, it achieves the reciprocation of the magnetic field generated by the plurality of electromagnetic coil units relative to the back plate in the preset period.

By means of sequentially loading the preset alternating currents to the electromagnetic coil units along the back plate in a reciprocation manner, the uniformity of the magnetic field may be improved, and the coverage area of the magnetic field may be increased, thereby improving the use efficiency of the target.

Optionally, the directions of the preset alternating currents loaded to two adjacent ones of said spaced-apart electromagnetic coil units at the same time are the same or opposite to each other, and the preset alternating currents have the same effective value.

In order to allow the magnetic fields generated by the electromagnetic coil units to have the same magnetic field intensity, the loaded preset alternating currents are configured to have the same effective value. If the loaded preset alternating currents have the same direction, then the electromagnetic coil units generate magnetic fields having the same magnetic field direction in accordance with physical characteristic of electromagnetism. In order to increase the magnetic field intensity orthogonal to the back plate, optionally, the directions of the preset alternating currents loaded to two adjacent ones of said spaced-apart electromagnetic coil units are opposite to each other. For example, the preset alternating current loaded to the first electromagnetic coil unit is a sinusoidal alternating current, and the preset alternating current loaded to the second electromagnetic coil unit, which is spaced apart from the first electromagnetic coil unit with the predetermined number of electromagnetic coil units located therein, is an alternating current of 180° phase difference from the sinusoidal alternating current, so that the direction of the magnetic field generated by the first electromagnetic coil unit is opposite to the direction of the magnetic field generated by the second electromagnetic coil unit. Thus, one of the electromagnetic coil units may be considered as a N pole, and the other of the electromagnetic coil units may be considered as a S pole, and the magnetic field generated by such two electromagnetic coil units is significantly larger than the magnetic field generated by only one electromagnetic coil unit.

In summary, according to the embodiments of the present disclosure, at a time in the preset period, the preset alternating currents are only loaded to the spaced-apart electromagnetic coil units, each two adjacent ones of which are spaced apart from each other with a predetermined number of electromagnetic coil units located therein, and the electromagnetic coil units loaded with the preset alternating currents at said time are different from the electromagnetic coil units loaded with the preset alternating currents at a next time. As a result, the electromagnetic coil units are loaded with the alternating currents at different times, such that all the electromagnetic coil units generate a magnetic field, which periodically reciprocates relative to the back plate. In this way, unreliability due to mechanical reciprocation of the back plate may be avoided, and the magnetic field may be uniformly distributed around the back plate. Therefore, the target sputtering method according to the embodiments of the present invention can improve the reliability of the device, and is applicable to a flat target sputtering device in the Large Generation Panel production line, and is also suitable for improving the existing flat target sputtering device, while improving the use efficiency of the target.

It should be noted that, in order to make the magnetic field generated by the two adjacent ones of said spaced-apart electromagnetic coil units be orthogonal to the back plate, and make the magnetic field generated by all the electromagnetic coil units cover the whole back plate, it is necessary for the concrete value of the predetermined number of the electromagnetic coil units to be much less than the number of all the electromagnetic coil units.

Further, if they are loaded with preset alternating currents of opposite directions, the electromagnetic coil units may be grouped. The preset alternating currents in a first direction are supplied into the electromagnetic coil units in odd-numbered groups, and the preset alternating currents in a second direction are supplied into the electromagnetic coil units in even-numbered groups. In such a case, the continuously arranged plurality of the electromagnetic coil units are divided into a plurality of groups, and each group comprises the same number of electromagnetic coil units. If the group number is an odd number, then such a group of electromagnetic coil units is referred to be as an odd-numbered group, and if the group number is an even number, then such a group of electromagnetic coil units is referred to be as an even-numbered group. The alternating current AC1 in the first direction and the alternating current AC2 in the second direction have the same frequency, the alternating current AC1 in the first direction and the alternating current AC2 in the second direction have the same effective value, and the alternating current AC1 in the first direction is phase-shifted with respect to the alternating current AC2 in the second direction by a phase difference of 180°. The phase of the alternating current in the first direction may be advanced by 180° with respect to the phase of the alternating current in the second direction, or the phase of the alternating current in the first direction may be delayed by 180° with respect to the phase of the alternating current in the second direction. A second embodiment will be provided to further describe a method of realizing the reciprocation of the magnetic field according to the difference between the odd-numbered groups and the even-numbered groups.

It should be noted that, by means of the target sputtering device and the method for sputtering the target using the target sputtering device according to the embodiments of the present disclosure, it can obtain more uniform functional film by sputtering the target, and the use efficiency of the target may be improved.

In particular, since the magnetic field in the target sputtering device according to the embodiments of the present disclosure is more uniformly distributed, the etching degrees of various regions of the target are substantially uniform when the target is sputtered by the target sputtering device, thereby the use efficiency of the target is improved. In such a way, it alleviates the problem that the target needs to be frequently replaced for the reason that some regions of the target are significantly faster etched than the other regions in the prior art, and the functional film formed in such a way is relatively uniform.

### Second Embodiment

Next, the method for sputtering the target according to the embodiment of the present disclosure will be described with reference to specific examples.

It should be noted that loading the preset alternating currents to the spaced-apart electromagnetic coil units, each two adjacent ones of which are spaced apart from each other with a predetermined number of electromagnetic coil units located therein, may be achieved by other manners. Hereinafter, a method for achieving the reciprocation of the magnetic field relative to the back plate will be described. In the method, the continuously arranged plurality of electromagnetic coil units are averagely grouped, the group located in an odd position acts as an odd-numbered group, and the group located in an even position acts as an even-numbered group. The odd-numbered groups are loaded with a first alternating current, and the even-numbered groups are loaded with a second alternating current, so as to achieve the reciprocation of the magnetic field relative to the back plate. Herein, the first alternating current and second alternating current have a phase difference of 180°.

Firstly, the electromagnetic coil units located underneath the back plate are grouped and numbered. For example, the electromagnetic coil units are sequentially labeled as 1, 2, 3, 4, . . . , N+1, N+2, . . . , 2N, 2N+1, . . . , 3N+1, . . . , M*N+1, . . . , (M+1)*N+1 from left to right, where M and N are both positive integers and N is much less than M. Each group comprises N electromagnetic coil units, and there are M groups. Provided that M is an even number, and the preset period is 1 s. Specifically, the first group includes the 1st, 2nd, 3rd, 4th, . . . , Nth electromagnetic coil units, the second group includes the (N+1)th, (N+2)th, . . . , (2N)th electromagnetic coil units, the third group includes the (2N+1)th, . . . , (3N)th electromagnetic coil units, and so on. The first group, the third group, . . . , the (M−1)th group belong to the odd-numbered groups, and the second group, the fourth group, . . . , the Mth group belong to the even-numbered groups.

The method for sputtering the target using the target sputtering device according to the embodiment of the present disclosure comprises steps of:

Step 1: at the time of the first second, supplying the alternating currents AC1 in the first direction to the first, (2N+1)th, (4N+1)th, . . . , (M*N+1)th electromagnetic coil units 12; at the same time, supplying the alternating currents AC2 in the second direction to the (N+1)th, (3N+1)th, (5N+1)th, . . . , ((M−1)*N+1)th electromagnetic coil units 12, wherein the phase of the AC1 is advanced or delayed by 180° with respect to the phase of the AC2, and the other electromagnetic coil units 12 are not supplied with the alternating currents. As shown in FIG. 10, the magnetic lines of the magnetic fields generated by the first, (2N+1)th, (4N+1)th, . . . , (M*N+1)th electromagnetic coil units are directed from left to right, and the magnetic lines of the magnetic fields generated by the (N+1)th, (3N+1)th, (5N+1)th, . . . , ((M−1)*N+1)th electromagnetic coil units are directed from right to left. Then, the target 13 located on the back plate 11 is sputtered through the magnetic fields shown in FIG. 10.

Step 2: at the time of the second second, supplying the alternating currents AC1 in the first direction to the second, (2N+2)th, (4N+2)th, . . . , (M*N+2)th electromagnetic coil units 12; at the same time, supplying the alternating currents AC2 in the second direction to the (N+2)th, (3N+2)th, (5N+2)th, . . . , ((M−1)*N+2)th electromagnetic coil units 12, wherein the other electromagnetic coil units are not supplied with the alternating currents. As shown in FIG. 11, the magnetic lines of the magnetic fields generated by the second, (2N+2)th, (4N+2)th, . . . , (M*N+2)th electromagnetic coil units are directed from left to right, and the magnetic lines of the magnetic fields generated by the (N+2)th, (3N+2)th, (5N+2)th, . . . , ((M−1)*N+2)th electromagnetic coil units are directed from right to left. Thus, the magnetic lines on the surface of the target are shifted towards the right side by a distance of a gap with respect to the magnetic field 14 in the step 1. Then, the target 13 located on the back plate 11 is sputtered through the magnetic fields shown in FIG. 11.

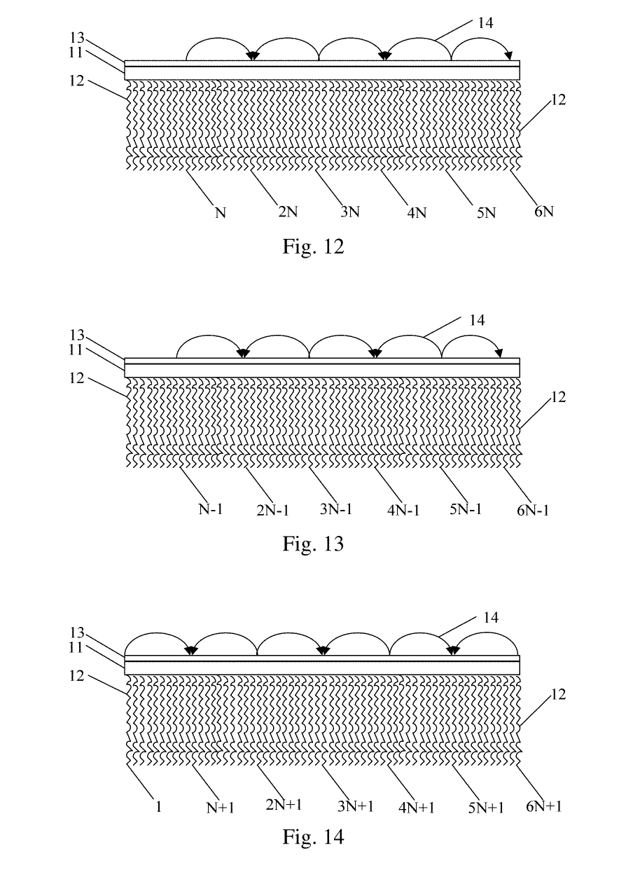

Step 3: similarly, at the time of the Nth second, supplying the alternating currents AC1 in the first direction to the Nth, (3N)th, (5N)th, . . . , ((M+1)*N)th electromagnetic coil units 12; at the same time, supplying the alternating currents AC2 in the second direction to the (2N)th, (4N)th, (6N)th, . . . , (M*N)th electromagnetic coil units 12, wherein the other electromagnetic coil units are not supplied with the alternating currents. As shown in FIG. 12, the magnetic lines of the magnetic fields generated by the Nth, (3N)th, (5N)th, . . . , ((M+1)*N)th electromagnetic coil units are directed from left to right, and the magnetic lines of the magnetic fields generated by the (2N)th, (4N)th, (6N)th, . . . , (M*N)th electromagnetic coil units are directed from right to left. Thus, the magnetic lines on the surface of the target are shifted towards the right side by a distance of a group of electromagnetic coil units with respect to the magnetic field 14 in the step 1. Then, the target 13 located on the back plate 11 is sputtered through the magnetic fields shown in FIG. 12.

Step 4: at the time of the (N+1)th second, supplying the alternating currents AC1 in the first direction to the (N−1)th, (3N−1)th, (5N−1)th, . . . , ((M+1)*N−1)th electromagnetic coil units 12; at the same time, supplying the alternating currents AC2 in the second direction to the (2N−1)th, (4N−1)th, (6N−1)th, . . . , (M*N−1)th electromagnetic coil units 12, wherein the other electromagnetic coil units are not supplied with the alternating currents. As shown in FIG. 13, the magnetic lines of the magnetic fields generated by the (N−1)th, (3N−1)th, (5N−1)th, . . . , ((M+1)*N−1)th electromagnetic coil units are directed from left to right, and the magnetic lines of the magnetic fields generated by the (2N−1)th, (4N−1)th, (6N−1)th, . . . , (M*N−1)th electromagnetic coil units are directed from right to left. Thus, the magnetic lines on the surface of the target are shifted towards the left side by a distance of a gap with respect to the magnetic field 14 in the previous step. Then, the target 13 located on the back plate 11 is sputtered through the magnetic fields shown in FIG. 13.

Step 5: similarly, at the time of the (2N)th second, supplying the alternating currents AC1 in the first direction to the first, (2N+1)th, (4N+1)th, . . . , (M*N+1)th electromagnetic coil units 12; at the same time, supplying the alternating currents AC2 in the second direction to the (N+1)th, (3N+1)th, (5N+1)th, . . . , ((M−1)*N+1)th electromagnetic coil units 12, wherein the phase of the AC1 is advanced or delayed by 180° with respect to the phase of the AC2, and the other electromagnetic coil units are not supplied with the alternating currents. As shown in FIG. 14, the magnetic lines of the magnetic fields generated by the first, (2N+1)th, (4N+1)th, . . . , (M*N+1)th electromagnetic coil units are directed from left to right, and the magnetic lines of the magnetic fields generated by the (N+1)th, (3N+1)th, (5N+1)th, . . . , ((M−1)*N+1)th electromagnetic coil units are directed from right to left. Then, the target 13 located on the back plate 11 is sputtered through the magnetic fields shown in FIG. 14.

Step 6: sequentially repeatedly performing the above steps, so that the magnet fields generated by the electromagnetic coil units are sequentially moved from left to right and then from right to left, the reciprocation is repeated so that the generated magnetic fields are orthogonal to the back plate and uniformly distributed around the surface of the target on the back plate. Thus, the target located on the back plate is more uniformly etched through the reciprocated magnetic fields, and the use efficiency of the target is improved due to a relatively larger magnetic field distribution.

It should be noted that, in the method for sputtering the target according to the embodiment of the present disclosure, it is possible to sequentially supply the alternating currents in the first direction to the electromagnetic coil units in only the odd-numbered groups for a preset time length, and periodically supply the alternating currents in the first direction, so that the magnetic field generated by the electromagnetic coil units in the odd-numbered groups is periodically reciprocated relative to the target. In this way, the magnetic field generated by the electromagnetic coil units is relatively uniformly distributed, thereby improving the use efficiency of the target. Similarly, it is possible to sequentially supply the alternating currents in the second direction to the electromagnetic coil units in only the even-numbered groups for a preset time length, and periodically supply the alternating currents in the second direction, so that the magnetic field generated by the electromagnetic coil units in the even-numbered groups is periodically reciprocated relative to the target. In this way, the magnetic field generated by the electromagnetic coil units is relatively uniformly distributed, thereby improving the use efficiency of the target. Optionally, the electromagnetic coil units in the odd-numbered groups are sequentially supply with the alternating currents in the first direction for a preset time length, while the electromagnetic coil units in the even-numbered groups are sequentially supply with the alternating currents in the second direction for a preset time length, thus, the generated magnetic field orthogonal to the back plate have a relatively large intensity, thereby facilitating the etching of the target.

It should be noted that the period of the reciprocation of the magnetic field in the embodiment of the present disclosure may be set according to the actual situation, and it is not particularly limited in the present disclosure.

In summary, in the method for sputtering the target according to the embodiment of the present disclosure, the magnetic field is configured to reciprocate on the surface of the target located on the back plate relative to the back plate, so that the probability of ion collision is the same and becomes larger under the action of the magnetic field. As a result, a majority of the target may be uniformly etched, the use efficiency of the target is effectively improved, the replacement frequency of the target is reduced, and the operation ratio of equipment is increased. Furthermore, in the method for sputtering the target according to the embodiment of the present disclosure, it is unnecessary for the device to mechanically move, thereby improving the reliability of the device, and the method is applicable to a flat target sputtering device in the Large Generation Panel production line, and is also suitable for improving the existing flat target sputtering device.

It should be noted that, when the target sputtering device according to the embodiment of the present disclosure is used to sputter the target, the magnetic field can reciprocate relative to the back plate so as to complete the target sputtering, whether the target is sputtered by the method according to the first embodiment or the method according to the second embodiment.

According to the embodiments of the present disclosure, the target sputtering device comprises a back plate and a plurality of electromagnetic coil units uniformly distributed underneath the back plate and insulated with each other. When alternating currents are loaded to the plurality of electromagnetic coil units, the plurality of electromagnetic coil units generate a magnetic field. Furthermore, the plurality of electromagnetic coil units are configured to generate a magnetic field, which is movable relative to the back plate and orthogonal to the back plate, in a preset period. Thus, the magnetic field orthogonal to the back plate is generated at each time in the preset period, and in the preset period, each of the electromagnetic coil units generates different magnetic fields at different times so that the magnetic field moves relative to the back plate. Since a time average value of magnetic induction intensity in the preset period at one position within an effective area of the surface of the back plate is identical to that at the other positions within an effective area of the surface of the back plate, and the electromagnetic coil units are uniformly distributed, the magnetic field is uniformly distributed around the back plate so that the distribution uniformity of the magnetic field generated by the target sputtering device is improved, thereby improving the use efficiency of the target.

It will be appreciated that various alternatives and modifications to the present disclosure may be made by the skilled person in the art without departing from the spirit and scope of the present disclosure. Thus, it is intended that the present disclosure includes such alternatives and modifications as long as these alternatives and modifications fall within the scope of the appended claims and their equivalents.

1. A target sputtering device, comprising:
a back plate; and
a plurality of electromagnetic coil units uniformly distributed underneath the back plate and insulated with each other,
wherein the plurality of electromagnetic coil units are configured to generate a magnetic field, which is movable relative to the back plate and orthogonal to the back plate, in a preset period.

2. The device according to claim 1, wherein the magnetic field generated by the plurality of electromagnetic coil units reciprocates relative to the back plate in the preset period.

3. The device according to claim 1, wherein the electromagnetic coil units are configured to be loaded with preset alternating currents such that:
at a time in the preset period, the preset alternating currents are only loaded to spaced-apart electromagnetic coil units, each two adjacent ones of which are spaced apart from each other with a predetermined number of electromagnetic coil units located therein, and
the electromagnetic coil units loaded with the preset alternating currents at said time are different from the electromagnetic coil units loaded with the preset alternating currents at a next time.

4. The device according to claim 3, wherein directions of the preset alternating currents loaded to two adjacent ones of said spaced-apart electromagnetic coil units at a said time are identical or opposite to each other, and the preset alternating currents have a same effective value.

5. The device according to claim 1, wherein the electromagnetic coil units comprise an iron core and coils wound around the iron core, and the electromagnetic coil units each have an equal number of coils.

6. The device according to claim 5, wherein the coils in the electromagnetic coil units have a shape of a rectangle, and a long side of the rectangle is parallel to the back plate and perpendicular to a long side of the back plate.

7. The device according to claim 6, wherein a short side of the rectangle has a length in a range of 50-500 mm.

8. The device according to claim 5, wherein two adjacent ones of the electromagnetic coil units are spaced apart from each other by a gap of 5-50 mm.

9. A method for sputtering a target using the target sputtering device according to claim 1, comprising a step of:
at a time in the preset period, loading preset alternating currents to only spaced-apart electromagnetic coil units, each two adjacent ones of which are spaced apart from each other with a predetermined number of electromagnetic coil units located therein,
wherein the electromagnetic coil units loaded with the preset alternating currents at said time are different from the electromagnetic coil units loaded with the preset alternating currents at a next time.

10. The method according to claim 9, further comprising a step of: sequentially loading the preset alternating currents to the electromagnetic coil units along the back plate in a reciprocation manner, during the preset period.

11. The method according to claim 9, wherein directions of the preset alternating currents loaded to two adjacent ones of said spaced-apart electromagnetic coil units at said time are identical or opposite to each other, and the preset alternating currents have a same effective value.

12. The device according to claim 2, wherein the electromagnetic coil units comprise an iron core and coils wound around the iron core, and the electromagnetic coil units each have an equal number of coils.

13. The device according to claim 3, wherein the electromagnetic coil units comprise an iron core and coils wound around the iron core, and the electromagnetic coil units each have an equal number of coils.

14. The device according to claim 4, wherein the electromagnetic coil units comprise an iron core and coils wound around the iron core, and the electromagnetic coil units each have an equal number of coils.

15. A method for sputtering a target using the target sputtering device according to claim 2, comprising a step of:
at a time in the preset period, loading preset alternating currents to only spaced-apart electromagnetic coil units, each two adjacent ones of which are spaced apart from each other with a predetermined number of electromagnetic coil units located therein,
wherein the electromagnetic coil units loaded with the preset alternating currents at said time are different from the electromagnetic coil units loaded with the preset alternating currents at a next time.

16. A method for sputtering a target using the target sputtering device according to claim 3, comprising a step of:
at a time in the preset period, loading preset alternating currents to only spaced-apart electromagnetic coil units, each two adjacent ones of which are spaced apart from each other with a predetermined number of electromagnetic coil units located therein,
wherein the electromagnetic coil units loaded with the preset alternating currents at said time are different from the electromagnetic coil units loaded with the preset alternating currents at a next time.

17. A method for sputtering a target using the target sputtering device according to claim 4, comprising a step of:
at a time in the preset period, loading preset alternating currents to only spaced-apart electromagnetic coil units, each two adjacent ones of which are spaced apart from each other with a predetermined number of electromagnetic coil units located therein,
wherein the electromagnetic coil units loaded with the preset alternating currents at said time are different from the electromagnetic coil units loaded with the preset alternating currents at a next time.

18. A method for sputtering a target using the target sputtering device according to claim 5, comprising a step of:
at a time in the preset period, loading preset alternating currents to only spaced-apart electromagnetic coil units, each two adjacent ones of which are spaced apart from each other with a predetermined number of electromagnetic coil units located therein,
wherein the electromagnetic coil units loaded with the preset alternating currents at said time are different from the electromagnetic coil units loaded with the preset alternating currents at a next time.

19. A method for sputtering a target using the target sputtering device according to claim 6, comprising a step of:
at a time in the preset period, loading preset alternating currents to only spaced-apart electromagnetic coil units, each two adjacent ones of which are spaced apart from each other with a predetermined number of electromagnetic coil units located therein,
wherein the electromagnetic coil units loaded with the preset alternating currents at said time are different from the electromagnetic coil units loaded with the preset alternating currents at a next time.

20. A method for sputtering a target using the target sputtering device according to claim 7, comprising a step of:
at a time in the preset period, loading preset alternating currents to only spaced-apart electromagnetic coil units, each two adjacent ones of which are spaced apart from each other with a predetermined number of electromagnetic coil units located therein,
wherein the electromagnetic coil units loaded with the preset alternating currents at said time are different from the electromagnetic coil units loaded with the preset alternating currents at a next time.
